(19) United States
(12) Patent Application Publication
(10) Pub. No.: US 2025/0316474 A1
(43) Pub. Date: Oct. 9, 2025

(54) HIGH MODULUS CARBON DOPED SILICON OXIDE FILM FOR MOLD STACK SCALING SOLUTIONS IN ADVANCED MEMORY APPLICATIONS

(71) Applicant: Lam Research Corporation, Fremont, CA (US)

(72) Inventors: Ananda K. Banerji, West Linn, OR (US); Katherine Elizabeth Haynes, Portland, OR (US); Soumana Hamma, Tigard, OR (US); Malay Milan Samantaray, Portland, OR (US); Pramod Subramonium, Portland, OR (US); Kapu Sirish Reddy, Portland, OR (US)

(21) Appl. No.: 18/866,461

(22) PCT Filed: May 17, 2023
(86) PCT No.: PCT/US2023/022608

§ 371 Date: Nov. 15, 2024

Related U.S. Application Data
(60) Provisional application No. 63/365,123, filed on May 20, 2022.

(51) Int. Cl. H01L 21/02; C23C 16/40; C23C 16/458; C23C 16/50; C23C 16/52; C23C 16/56; H01J 37/32

(52) U.S. Cl. CPC H01L 21/02164; C23C 16/401; C23C 16/4583; C23C 16/50; C23C 16/52; C23C 16/56; H01J 37/3244; H01L 21/02211; H01J 2237/3321

(57) ABSTRACT

Provided are reduced temperature plasma enhanced chemical vapor deposition processes for producing high modulus oxide thin films on a substrate. The substrate temperature for deposition of the oxide thin film is less than about 700° C.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

The evolution of chip design demands continual improvement of circuit speed and reliability. This gives rise to a need for compacting devices into higher packing density to achieve faster transistor speed. Nevertheless, downsizing of devices is not always preferable. Increasing density up to the subatomic level will cause RC (resistance capacitance) delay, which degrades the transistor performance. A solution is to use low dielectric constant inter-metallic dielectric films to replace conventional silicon oxide films.

A material that may be considered suitable for such a task is a carbon-doped silicon dioxide film. Using this material to divide a metal line may yield a device having reduced propagation delay, cross-talk noise and power dissipation. Yet replacing a silicon dioxide film may cause adverse effects on other integration modules. One long-standing problem is etching of the carbon-doped silicon oxide film. Etching profiles can deviate due to excessive carbon byproducts releasing from the film. Furthermore, the excess carbons arising from the film can interfere with etching and stop it prior to reaching a desired depth, increasing the likelihood of incomplete etching. Carbon content can also cause excessive micro loading (the difference in etch rate between an isolated trench and a dense trench) which is difficult to adjust. For these reasons, a high carbon content in a film is not typically desirable except for reducing its dielectric constant. Accordingly, a precisely controlled carbon content in a carbon doped silicon oxide film would be advantageous, particularly for 3D NAND technology wherein memory cells are stacked vertically in layers.

The background description provided herein is for the purposes of generally presenting the context of the disclosure. Work of the presently named inventors, to the extent it is described in this background section, as well as aspects of the description that may not otherwise qualify as prior art at the time of filing, are neither expressly or impliedly admitted as prior art against the present disclosure.

### SUMMARY

Methods and apparatuses for processing semiconductor substrates, and semiconductor devices, are provided herein. Various described methods and apparatuses relate to thin films produced by reduced temperature plasma enhanced chemical vapor deposition that can be useful in large area gap fill applications, such as in the formation of advanced 3D NAND devices. The thin films have improved mechanical properties without sacrificing electrical properties or other properties facilitating ease of integration.

Accordingly, in a first aspect, the present invention encompasses a method of plasma enhanced chemical vapor deposition of a thin film. In some embodiments, the method includes providing a substrate in a deposition chamber at a substrate temperature of less than about 700° C.; generating a plasma of at least one process gas comprising at least one reactant; contacting the substrate with the plasma in the deposition chamber; and depositing the thin film on the substrate, the thin film having a Young's modulus of at least 70 GPa.

In some embodiments, the reactant is a silicon-containing gas source, an aluminum-containing gas source or a boron-containing gas source.

In some embodiments, the thin film is silicon monoxide, silicon dioxide, silicon nitride, silicon oxynitride, aluminum oxide, boron carbide or boron nitride.

In some embodiments, the thin film is a doped thin film.

In some embodiments, the doped thin film is silicon oxide doped with carbon, nitrogen, boron, phosphorus or a combination thereof.

In some embodiments, the doped thin film has a modulus of at least 90 GPa.

In some embodiments, the doped thin film is boron carbide doped with silicon, nitrogen, germanium, magnesium, nickel or a combination thereof.

In some embodiments, the doped thin film is boron nitride doped with bismuth, zinc, copper or a combination thereof.

In some embodiments, the doped thin film is silicon nitride doped with aluminum, phosphorus, carbon, oxygen or a combination thereof.

In some embodiments, the doped thin film is aluminum oxide doped with erbium, titanium, chromium or a combination thereof.

In some embodiments, the plasma is generated in situ or remotely.

In some embodiments, the thin film has a thickness of less than 300 angstroms.

In some embodiments, the thin film has a dielectric constant of about 4 to about 4.5.

In a second aspect, the present invention encompasses a method for plasma enhanced chemical vapor deposition of carbon-doped silicon oxide film on a substrate. In some embodiments, the method includes providing the substrate in a deposition chamber at a substrate temperature of less than about 700° C.; generating a plasma of a process gas comprising a silicon-containing gas source and a carrier gas, and a carbon-containing gas source; contacting the substrate with the plasma in the deposition chamber; and depositing a thin film of carbon-doped silicon dioxide on the substrate, the thin film having a Young's modulus of at least 70 GPa.

In some embodiments, the silicon-containing gas source is a gas of a compound of the formula SiHₙR¹₄₋ₙ (I), SiHₙ(OR²)₄₋ₙ (II), O(Si(R³₃))₂ (III) or a combination thereof, wherein R¹, R² and R³ are each independently optionally substituted aliphatic, optionally substituted alkyl, optionally substituted heteroalkyl, optionally substituted aryl, optionally substituted heteroaryl, optionally substituted cyclyl or optionally substituted heterocyclyl, and n is an integer of 0 to 4.

In some embodiments, the silicon-containing gas source is a gas such as silane, tetramethylsilane, tetramethoxysilane, tetraethoxysilane, hexamethyldisilazane, hexamethyl disiloxane and combinations thereof.

In some embodiments, the silicon-containing gas source contains tetramethylsilane and silane.

In some embodiments, the carbon-containing gas source is a gas such as carbon dioxide, carbon monoxide, methane, ethane and combinations thereof.

In some embodiments, the carbon-containing gas source also includes a carrier gas such as argon, helium, hydrogen, nitrous oxide, nitrogen and combinations thereof.

In some embodiments, the carbon-doped silicon oxide film has a modulus of at least 90 GPa.

In some embodiments, the carbon-doped silicon oxide film has about 5% (atomic) carbon content or less.

In some embodiments, the pressure in the deposition chamber is maintained between about 1 and about 8 Torr.

In some embodiments, the substrate temperature is greater than about 400° C. and less than about 650° C.

In some embodiments, the ratio of the carbon-containing gas source to the silicon-containing gas source is between about 150:1 to about 10:1.

In some embodiments, the plasma is generated in situ or remotely.

In some embodiments, the thin film has a thickness of less than 300 angstroms.

In some embodiments, the thin film has a dielectric constant of about 4 to about 4.5.

In a third aspect, the present disclosure encompasses a composition. In some embodiments, the composition is a carbon-doped silicon oxide film having a thickness of less than 300 angstroms, a Young's modulus of at least 90 GPa, a dielectric constant of about 4 to about 4.5, and a carbon content of about 5% (atomic) or less.

In a fourth aspect, the present disclosure encompasses an apparatus for processing substrates. In some embodiments, the apparatus includes a reaction chamber; a substrate support configured to support a substrate in the reaction chamber; one or more inlets for introducing reactants to the reaction chamber; one or more outlets for removing material from the reaction chamber; and a controller having at least one processor and a memory, wherein the at least one processor and the memory are communicatively connected with one another, and the memory stores computer-executable instructions for controlling the at least one processor to cause providing a substrate in a deposition chamber at a substrate temperature of less than about 700° C.; generating a plasma of at least one process gas comprising at least one reactant; contacting the substrate with the plasma in the deposition chamber; and depositing the thin film on the substrate, the thin film having a Young's modulus of at least 70 GPa.

In some embodiments, the thin film has a thickness of less than 300 angstroms.

In some embodiments, the thin film has a dielectric constant of about 4 to about 4.5.

In a fifth aspect, the present disclosure encompasses an apparatus for forming a carbon-doped silicon oxide film on a substrate. In some embodiments, the apparatus includes a reaction chamber; a substrate support configured to support the substrate in the reaction chamber; one or more inlet for introducing reactants to the reaction chamber; one or more outlet for removing material from the reaction chamber; a plasma generator configured to deliver a plasma to the reaction chamber; and a controller having at least one processor and a memory, wherein the at least one processor and the memory are communicatively connected with one another, and the memory stores computer-executable instructions for controlling the at least one processor to cause: (i) receiving the substrate in the reaction chamber, (ii) flowing a process gas comprising a silicon-containing source into the reaction chamber, and (iii) generating and delivering the plasma from a carbon-containing gas source to the reaction chamber to form the carbon-doped silicon oxide film on the substrate, wherein the carbon-doped silicon oxide film has: a Young's modulus of about 90 GPa or greater, and a dielectric constant of about 4 to about 4.5.

In some embodiments, the carbon-doped silicon oxide film has a thickness of less than 300 angstroms.

In some embodiments, the carbon-doped silicon oxide film has a carbon content of about 5% (atomic) or less.

These and other aspects are described further below with reference to the drawings.

### BRIEF DESCRIPTION OF THE DRAWINGS

FIG. 1 is a process flow diagram depicting operations for a method of plasma enhanced chemical vapor deposition of a thin film in accordance with certain disclosed embodiments.

FIG. 2 is a process flow diagram depicting operations for a method of depositing and then optionally annealing a thin film in accordance with certain disclosed embodiments.

FIGS. 3-12 are schematic illustrations of depositing and annealing a doped silicon oxide film in a 3D NAND fabrication context in accordance with certain disclosed embodiments.

FIGS. 13-15 are schematic illustrations of example process chambers and tools for performing certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Definitions

As used herein, the term “about” means +/−10% of any recited value, unless otherwise specified. As used herein, this term modifies any recited value, range of values or endpoints of one or more ranges.

As used herein, the terms “top”, “bottom”, “upper”, “lower”, “above”, and “below” are used to provide a relative relationship between structures. The use of these terms does not indicate or require that a particular structure must be located at a particular location in the apparatus.

As used herein, the phrase “at least one of A, B, and C” should be construed to mean a logical (A or B or C), using a non-exclusive logical “or”, and should not be construed to mean “at least one of A, at least one of B and at least one of C”.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight-and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus, Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which Lis C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “deposition” or “vapor deposition” is meant a process in which a layer (e.g., a metal) is formed on one or more surfaces of a substrate from vaporized precursor composition(s), for example in the case of a deposited metal layer, including one or more metal containing compounds. The precursor compositions are vaporized and directed to and/or contacted with one or more surfaces of a substrate (i.e., semiconductor substrate or semiconductor assembly) placed in a deposition chamber. Typically the substrate is heated. These precursor compositions form a non-volatile, thin, uniform layer on the surface(s) of the substrate. One operation of the method is one cycle, and the process can be repeated for as many cycles necessary to obtain the desired layer thickness.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

For the purposes of this disclosure, “metal” used in this context should be understood to mean conductor with a maximum resistivity of 500 micro Ohm cm, including metals and conductive metal salts, in particular conductive metal nitrides, e.g., TiN.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like. The term “semiconductor substrate” or “substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

“Silicon oxide” is referred to herein as including chemical compounds including silicon and oxygen atoms, including any and all stoichiometric possibilities for SiₓO_{y}, including integer values of x and y and non-integer values of x and y. For example, “silicon oxide” includes compounds having the formula SiOₙ, where 1≤n≤2, where n can be an integer or non-integer values. “Silicon oxide” can include sub-stoichiometric compounds such as SiO_{1.8}. “Silicon oxide” also includes silicon dioxide (SiO₂) and silicon monoxide (SiO). “Silicon oxide” also includes both natural and synthetic variations and also includes any and all crystalline and molecular structures, including tetrahedral coordination of oxygen atoms surrounding a central silicon atom. “Silicon oxide” also includes amorphous silicon oxide and silicates.

By “silyl” is meant a —SiR¹R²R³ or —SiR¹R²—group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “substituted” is meant having one or more substituent moieties whose presence does not interfere with the desired function or reactivity. Examples of substituents alkyl, alkenyl, alkynyl, cycloalkyl (non-aromatic ring), Si(alkyl)₃, Si(alkoxy)₃, alkoxy, amino, alkylamino, alkenylamino, amide, amidine, guanidine, hydroxyl, thioether, alkylcarbonyl, alkylcaronyloxy, alkoxycarbonyloxy, carbonate, alkoxycarbonyl, aminocarbonyl, alkylthiocarbonyl, phosphate, phosphate ester, phosphonato, cyano, halo, acylamino, imino, sulfhydryl, alkylthio, thiocarboxylate, dithiocarboxylate, sulfate, sulfato, sulfonate, sulfamoyl, sulfonamide, nitro, nitrile, azido, heterocyclyl, ether, ester, silicon-containing moieties, thioester or a combination thereof. The substituents may themselves be substituted. For instance, an amino substituent may itself be mono or independently disubstituted by further substituents defined above, such as alkyl, alkenyl, alkynyl, and cycloalkyl (non-aromatic ring).

By “unsubstituted” is meant any open valence of an atom being occupied by hydrogen. Also, if an occupant of an open valence position on an atom is not specified, then it is hydrogen.

A person of ordinary skill in the art would recognize that the definitions provided above are not intended to include impermissible substitution patterns (e.g., methyl substituted with five different groups, and the like). Such impermissible substitution patterns are easily recognized by a person of ordinary skill in the art. Any functional group disclosed herein and/or defined above can be substituted or unsubstituted, unless otherwise indicated therein.

Recent advances in semiconductor fabrication technology have allowed for increasing the density of elements, such as memory cells in a memory device, on a substrate. For example, in 3D NAND technology tall structures are designed in order to improve device density scaling. New challenges arise from the increased size of these structures. As described herein, novel materials and processing techniques have been developed to address these challenges, including large area gap fill.

In the 3D NAND fabrication integrated flow, alternating oxide and nitride or polysilicon layers are deposited in a staircase pattern. After the staircase is formed, it is filled by an oxide layer that will be subsequently annealed, polished, and etched to pattern the contacts. Conventional oxide films shrink after the thermal anneal step, causing displacement, deformation and tilt in the adjacent features and the patterned vias, which in turn results in device failure. Poor thermal stability may also cause film and structure cracking in various locations of the device. The thermal stability becomes even more challenging for advanced nodes, where the aspect ratio and volume of the oxide materials are significantly higher.

In typical current 3D NAND manufacturing, the “mold stack” comprising a stack of 24to 64 pairs of oxide and nitride layers (such as, silicon oxide (SiO₂)/silicon nitride (Si₃N₄) layers) is typically deposited in a plasma-enhanced chemical vapor deposition (PECVD) dielectric deposition tool. The SiO₂ layer and Si₃N₄ layer are deposited sequentially on each station (also referred to as a pedestal) without moving the wafer until the entire stack, or a substantial fraction of the stack, is deposited. Vertical channels are then etched down through the oxide and nitride layers in the mold stack by high aspect ratio etching, and filled with metal to form contacts. Then, a thick photoresist layer is applied and patterned, one set of oxide/nitride pairs is etched and then the photoresist pattern is shrunken and the next pair of oxide/nitride layers is etched. This sequence is repeated to create a stair step structure at the edge of the array. After a thick oxide layer is deposited and planarized, a word line slot mask is applied and a slot is etched down through all of the oxide/nitride layer pairs. The nitride layers are then etched out through the word line slot. A gate stack of silicon dioxide, silicon nitride, aluminum oxide, tungsten and tantalum nitride is then deposited and etched back and finally the slot is filled with oxide and tungsten.

Large area gap fill challenges are encountered in the fabrication of taller structures, which involves deposition of thicker high-quality films. In 3D NAND, for example, thick silicon oxide films are used for isolation purposes. Conventional oxide films suffer from a high stress that causes wafer bow and pattern distortion when the films are made thicker that, in turn, result in wafer handling problems and integration issues such as excessive lithography overlay and poor focus. For conventional silicon oxide films, lowering the film stress results in high moisture absorption which can lead to oxidation and high resistance in metal contacts. Also, these films have high stress shift and film shrinkage upon thermal treatment that amplifies the pattern distortion problems. In addition, demand for ever thicker films leads to ever increasing Chemical Mechanical Polish (CMP) time to planarize the device. So, it is desired to increase the CMP rate to reduce the overall processing cost of the device.

A sufficiently thick low stress film with high thermal stability, low moisture absorption and excellent dielectric properties, such as low dielectric constant and high breakdown voltage, would be desirable for large area gap fill and other applications in current and developing semiconductor processing techniques. For large area gap fill and other applications, such a film should allow low cost processing and avoid problems depositing to aggregate thicknesses exceeding 5 micrometers (microns (μm)), such as up to 10 μm or up to 20 μm, or more. Thick films can be deposited at thicknesses up to 20 μm or more by a single-pass deposition.

A potential candidate with the appropriate physical characteristics is a doped oxide film. However, the common industry method used for deposition of such films is sub-atmospheric chemical vapor deposition (SACVD). While SACVD can produce films with high CMP rate and low stress after annealing, the deposition rate is very slow which increases cost. In addition, the films absorb moisture, shrink unacceptably and tend to crack when deposited to thicknesses of many micrometers.

Conventional oxide films have a nominal modulus in the range of 75 GPa, which are suitable for high aspect ratio memory OPOP (oxide/polysilicon) and ONON (oxide/nitride) applications. Yet they are subject to cause line bending and collapse when thinner layers are applied. However, a high modulus thin film deposited in accordance with certain disclosed embodiments allows thinning of oxide layers for highest stack integration layers. Such thin films may have one or more of the following characteristics: appropriate dielectric constants, high density, matching or exceeding wet etch rates, and maintenance of high electrical qualities. Any of these characteristics is advantageous to the successful integration of future memory technology nodes, and also useful when the number of mold stack ONON pairs is increased as demanded by advanced technology nodes.

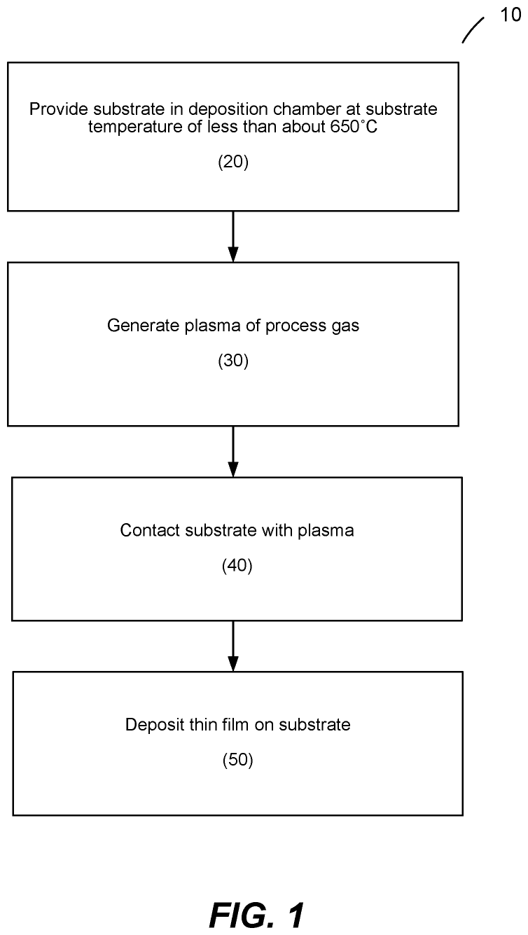

FIG. 1 schematically shows a non-limiting process for thin film deposition. Process 10 illustrates a method for plasma enhanced chemical vapor deposition of a thin film. In an operation 20, a substrate is provided in a deposition chamber at a substrate temperature of less than about 700° C., for example 650° C. or less. The implementations disclosed below describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, LEDs, photovoltaic panels and the like.

In various embodiments, the substrate is a semiconductor substrate. The substrate may be a silicon wafer, e.g., a 200-mm wafer, a 300-mm wafer, or a 450-mm wafer, including wafers having one or more layers of material, such as dielectric, conducting, or semi-conducting material deposited thereon. In some embodiments, the substrate temperature is from about 400° C. to less than about 650° C. In some embodiments, the substrate temperature is about 350° C. to about 500° C. In some embodiments, the substrate temperature is about 525° C. to about 575° C.

In some embodiments, the pressure in the deposition chamber is maintained at about 1 to about 20 Torr, for example about 1 to about 8 Torr. In some embodiments, the pressure in the deposition chamber is maintained at about 2 to about 5 Torr. In some embodiments, the plasma power is 150-800 Watts/station. In some embodiments, the plasma power is 200-500 Watts/station.

In some embodiments, a plasma is generated in an operation 30. The plasma may be generated in situ (within the deposition chamber; also referred to as a direct plasma) or remotely (in a separate apparatus, external to the deposition chamber). In some embodiments, a plasma of reactive species is formed. The plasma species could include electrons, positive ions, neutral species, radicals and other plasma species. In some embodiments, a plasma is formed from at least one process gas comprising at least one reactant. In addition to the reactant, the process gas may also include a carrier gas. In some embodiments, the carrier gas is a noble gas such as argon, neon, krypton, xenon or helium. In some instances, the plasma may comprise other species, for example, nitrogen atoms, nitrogen radicals, nitrogen plasma or combinations thereof.

The choice of reactant utilized as the process gas is dependent upon the thin film desired. In some embodiments, when the thin film is silicon oxide, silicon dioxide, silicon nitride or silicon oxynitride; the reactant is a silicon-containing gas source.

Silicon-containing precursors suitable for use in accordance with disclosed embodiments include polysilanes (H₃Si—(SiH₂)ₙ—SiH₃), where n≥0. Examples of silanes are silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials when a plasma is struck, a halosilane may not be introduced to the chamber when a plasma is struck in some embodiments, so formation of a reactive halide species from a halosilane may be mitigated. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, diisopropylaminosilane (DIPAS), di-sec-butylaminosilane, tert-butylsilanamine, bi(tertiarybutylamino) silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)).

The silicon-containing gas source may be a gas of a compound of the formula SiHₙR¹₄₋ₙ (I), SiHₙ(OR²)₄₋ₙ (II), O(Si(R³₃)); (III) or a combination thereof, wherein R¹, R² and R³ are each independently optionally substituted aliphatic, optionally substituted alkyl, optionally substituted heteroalkyl, optionally substituted aryl, optionally substituted heteroaryl, optionally substituted cyclyl or optionally substituted heterocyclyl, and n is an integer of 0 to 4.

Suitable silicon-containing reactants include dimethylaminotrimethylsilane, diethylaminotrimethylsilane, di-isopropylaminotrimethylsilane, piperidinotrimethylsilane, 2,6-dimethylpiperidinotrimethylsilane, di-sec-butylaminotrimethylsilane, isopropyl-sec-butylaminotrimethylsilane, tert-butylaminotrimethylsilane, isopropylaminotrimethylsilane, tert-pentylaminotrimethylsilane, diethylaminodimethylsilane, dimethylaminodimethylsilane, di-isopropylaminodimethylsilane, piperidinodimethylsilane, 2.6-dimethylpiperidinodimethylsilane, di-sec-butylaminodimethylsilane, isopropyl-sec-butylaminodimethylsilane, tert-butylaminodimethylsilane, iso-propylaminodimethylsilane, tert-pentylaminodimethylaminosilane, dimethylaminomethylsilane, diethylaminodimethylsilane, di-isopropylaminomethylsilane, isopropyl-sec-butylaminomethylsilane, 2,6-dimethylpiperidinomethylsilane, di-sec-butylaminomethylsilane, bis(dimethylamino)methylsilane, bis(diethylamino)methylsilane, bis(di-isopropylamino)methylsilane, bis(isopropyl-sec-butylamino)methylsilane, bis(2,6-dimethylpiperidino)methylsilane, bis(piperidino)methylsilane, bis(isopropylamino)methylsilane, bis(tert-butylamino)methylsilane, bis(sec-butylamino)methylsilane, bis(tert-pentylamino)methylsilane, bis(isobutylamino)methylsilane, bis(cyclohexylamino)methylsilane, bis(isopropylamino)dimethylsilane, bis(isobutylamino)dimethylsilane, bis(sec-butylamino)dimethylsilane, bis(tert-butylamino)dimethylsilane, bis(tert-pentylamino)dimethylsilane, bis(cyclohexylamino)dimethylsilane and combinations thereof.

In some embodiments, the silicon-containing gas source is a gas such as silane, tetramethylsilane, tetramethoxysilane, tetraethoxysilane, hexamethyldisilazane, hexamethyl disiloxane and combinations thereof.

In some embodiments, the silicon-containing gas source contains tetramethylsilane and silane.

In some embodiments, the thin film is aluminum oxide; and the reactant is an aluminum-containing gas source. In some embodiments, the reactant is trimethylaluminum, aluminum tris-isopropoxide, aluminum trichloride, or aluminum acetylacetonate.

In some embodiments, the thin film is boron carbide or boron nitride; and the reactant is a boron-containing gas source. In some embodiments, the reactant is trimethylboron, boron trichloride, or triethylboron.

In some embodiments, the thin film formed by the plasma enhanced chemical vapor deposition methods of the present disclosure is a doped thin film. In some embodiments, the thin film is silicon dioxide doped with carbon, nitrogen, boron, phosphorus or a combination thereof. In some embodiments, the source of boron dopant is triethylborate (TEB). In some embodiments, the source of phosphorus dopant is triethylphosphate (TEPO). In some embodiments, the carbon dopant is carbon dioxide, carbon monoxide, methane, ethane or a combination thereof. In some embodiments, the carbon-containing gas source (dopant) also includes a carrier gas such as argon, helium, hydrogen, nitrous oxide, nitrogen and combinations thereof. In some embodiments, the flow ratio of carrier gas to carbon-containing gas source is up to 3:1.

In some embodiments, the film is boron carbide doped with silicon, nitrogen, germanium, magnesium, nickel or a combination thereof. In some embodiments, the film is boron nitride doped with bismuth, zinc, copper or a combination thereof. In some embodiments, the thin film is silicon nitride doped with aluminum, phosphorus, carbon, oxygen or a combination thereof. In some embodiments, the thin film is aluminum oxide doped with erbium, titanium, chromium or a combination thereof. In some embodiments, the thin film is a silicon-doped carbon material. In some embodiments, the thin film is silicon carbide doped with oxygen, nitrogen or a combination thereof.

In some embodiments, the thin film formed by the plasma enhanced chemical vapor deposition methods of the present disclosure is a carbon-doped silicon oxide thin film. The carbon-containing gas source dopant may be a gas such as carbon dioxide, carbon monoxide, methane, ethane or a combination thereof. The ratio of the carbon-containing gas source (dopant) to silicon-containing gas source (reactant) is between about 150:1 to about 10:1.

Returning to FIG. 1, in operation 40 the substrate is contacted with plasma of the process gas; the process gas containing at least one reactant. In some embodiments, the process gas also includes a carrier gas. In some embodiments the process optionally includes one or more dopants.

In operation 50, a thin film is deposited on the substrate. The thin film deposited may have a thickness of less than 300 angstroms, a Young's modulus of at least 70 GPa and a dielectric constant of about 4 to about 4.5. In some embodiments, the thin film is a carbon-doped silicon dioxide thin film having a Young's modulus of at least 90 GPa, a thickness of less than 300 angstroms, a carbon content of about 5% (atomic) or less, and a dielectric constant of about 4 to about 4.5. In some embodiments, the carbon-doped thin film may have no detectable carbon content. In some embodiments, the thin film not only has a high Young's modulus (e.g., at least 70 GPa, for example 90 GPa or more) and thus greater mechanical strength, but also retains the electrical properties and dielectric constant of conventional silicon oxides which have a lower Young's modulus (e.g., less than 70 GPa). In some embodiments, the thin film has a Young's modulus of 100 or more. In some embodiments, the thin film matches or exceeds the wet etch rate and/or density of conventional silicon oxides. The conventional oxide films formed by plasma enhanced chemical vapor deposition of tetraethylorthosilicate (TEOS) as the silicon-containing gas source or undoped silicate glass (USG) have Young's modulus values in the range of 70-80 GPa. For such conventional oxide films, disadvantageous line bending and line collapse can be anticipated at a 40 nm or lower pitch length (when thinner oxide layers are utilized).

In some embodiments, the plasma enhanced chemical vapor deposition of carbon-doped silicon oxide thin films include a substrate temperature of about 400 to about 600° C.; a deposition chamber pressure of about 1 to about 7 Torr; ratio of CO₂ to silicon-containing compound of about 40:1; and a plasma power of about 250-750 W/station, in accordance with the process shown in FIG. 1. In some embodiments, the flow rate of silicon-containing gas source may be about 50 to about 100 sccm/station and the flow rate of CO₂ may be about 1000 to about 5000 sccm/station.

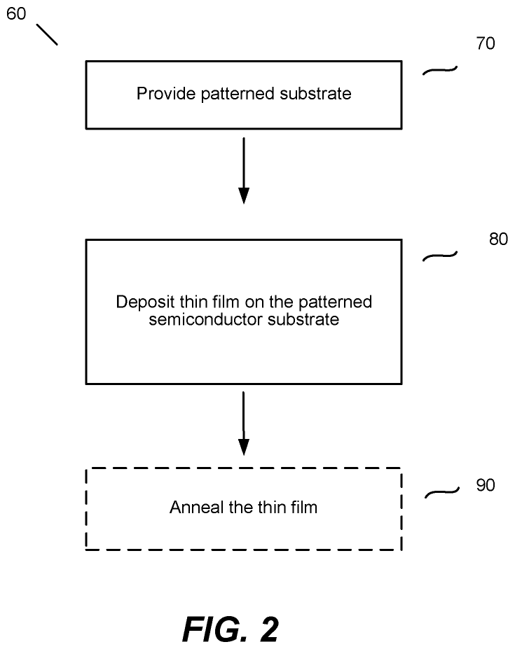

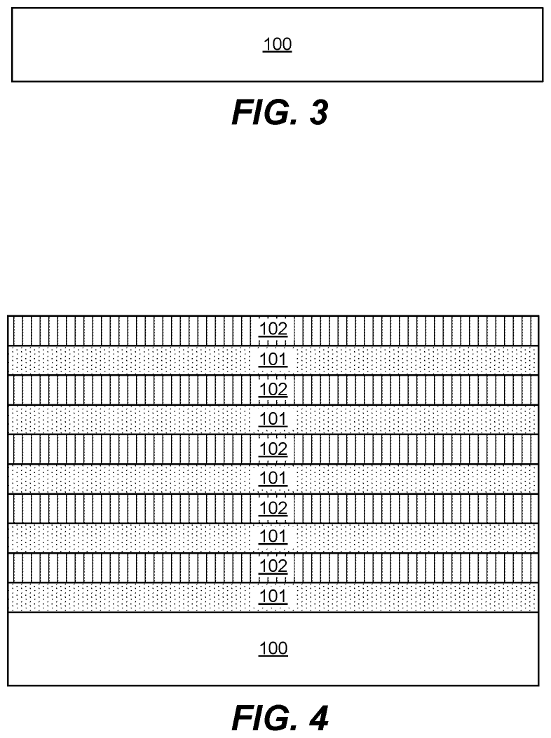

FIG. 2 schematically shows a non-limiting process for plasma enhanced chemical vapor deposition of a thin film. Process 60 illustrates a method of depositing and optionally annealing a doped silicon oxide film configured to expand upon annealing. In some embodiments, annealing may be performed at about 500 to about 1000° C. for about 10 to about 60 minutes in the presence of nitrogen gas. At 70, a patterned semiconductor substrate is provided, such as to a processing chamber of a chemical deposition tool. In some embodiments, the pattern is a staircase pattern of alternating oxide and nitride layers is formed on a substrate. An example substrate 100 is provided as a schematic illustration in FIG. 3.

The method involves, at 80, depositing a thin film (such as, a doped silicon oxide film) on a patterned semiconductor substrate. The thin film may, for example, have a thickness of at least 5 μm, for example up to 10 μm, or up to 20 μm, or more. The thin film may be deposited at a high rate of at least 1 μm per minute, e.g., about 1.25 μm/min, or more. In some embodiments, deposition of the thin film may be preceded by deposition of an undoped silicon oxide liner, for example having a thickness of about 200-2000 Å.

At 90, the doped silicon oxide film is then optionally annealed to a temperature above the film glass transition temperature. At the glass transition temperature, the film starts to expand and relax and film stress is reduced. In some embodiments, the annealing of the doped silicon oxide film may cause reflow of the film to occur.

Post-deposition annealing may be performed on the substrate in the same processing chamber or a different processing chamber. In some examples, post annealing can be performed in a processing chamber for a period in a range from 20 to 60 minutes at a temperature in a range from 500° C. to 950° C. In some examples, the annealing can be performed nitrogen (N₂) or another inert gas. In some examples, the annealing is performed for 30 minutes at 750° C. in N₂.

In various embodiments, the oxide layer deposited is a silicon oxide layer. In various embodiments, the nitride layer deposited is a silicon nitride layer. Each oxide and nitride layer is deposited to about the same thickness, such as between about 10 nm and about 100 nm, or about 350 Å in some embodiments. The oxide layers may be deposited at a deposition temperature of between about room temperature and about 600° C., for example.

Oxide and nitride layers for forming the alternating oxide and nitride film stack may be deposited using any suitable technique, such as atomic layer deposition (ALD), plasma enhanced atomic layer deposition (PEALD), chemical vapor deposition (CVD), plasma enhanced chemical vapor deposition (PECVD), or sputtering. In various embodiments, the oxide and nitride layers are deposited by PECVD.

The film stack may include between 48 and 512 layers of alternating oxide and nitride layers, whereby each oxide or nitride layer constitutes one layer. The film stack including the alternating oxide and nitride layers may be referred to as an ONON stack.

FIG. 4 shows an example schematic illustration of a substrate 100 with alternating oxide (101) and nitride (102) films deposited on the substrate 100. Note that while the structure shown in FIG. 4 shows an oxide deposited first, followed by nitride, oxide, nitride, etc., nitride may be deposited first, followed by oxide, nitride, oxide, etc.

Following deposition of the ONON stack, channels (not shown in FIG. 4) may be etched in the substrate. Subsequently, the staircase pattern is formed on the substrate. A “staircase pattern” as referred to herein includes two or more steps, each step including an oxide and a nitride layer. It will be understood that the top layer of each set of oxide and nitride layers may be either an oxide or a nitride for formation of steps in a staircase. In various embodiments, the staircase pattern includes between 24 and 256 steps, for example. The staircase pattern may be formed using a variety of patterning techniques. For example, one technique may include depositing a sacrificial layer over the substrate and masking regions of the substrate to etch each set of oxide and nitride layers to form the staircase.

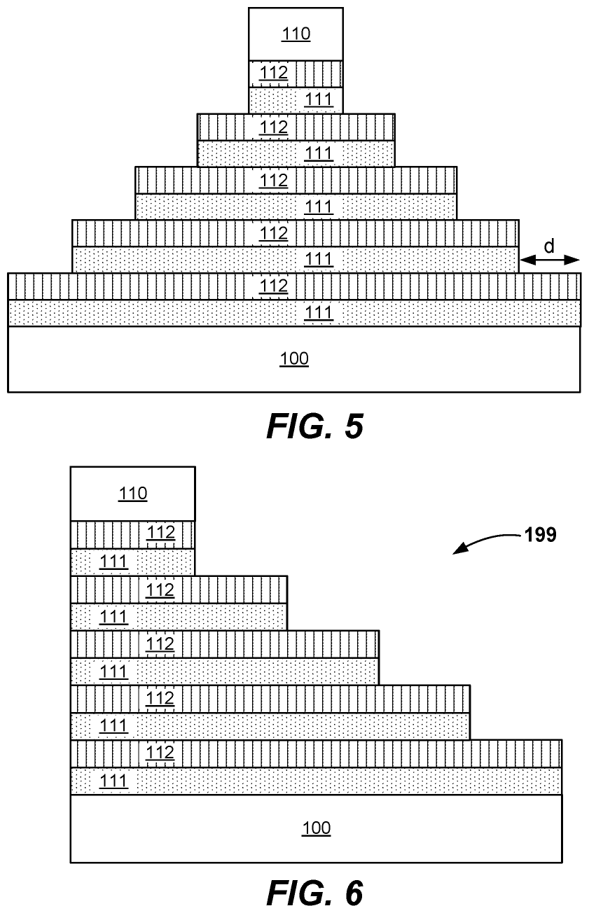

FIG. 5 provides an example of a substrate 100 including a staircase pattern of oxide (111) and nitride (112) layers with a hardmask 110 over the topmost nitride layer. Although FIG. 5 shows four steps of a staircase pattern, it will be understood that a staircase pattern will typically have many more steps, for example between 24 and 256 steps. Each step includes a nitride and oxide layer, and distanced as shown by “d” in FIG. 5 between, for example, about 150 nm and about 1000 nm, such as about 500 nm. This region of each step extending out from the edge of the step above it may be referred to as a “pad.”

For purposes of discussion, the following discussion and subsequent schematic illustrations of the substrate will include a half view 199 as shown in FIG. 6.

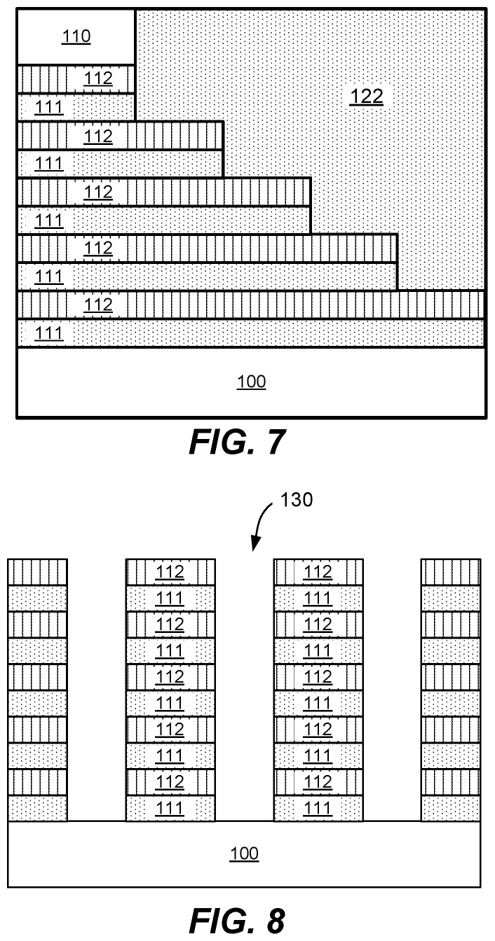

An oxide film is deposited over the staircase pattern on the substrate. In the 3D NAND context, the deposited doped film may be tuned to expand on annealing and to exhibit substantially zero as-deposited stress and stress shift post-anneal. FIG. 7 shows an example substrate 100 including the ONON staircase, hardmask 110, and doped oxide film 122 configured to expand upon annealing 122 deposited over the staircase.

Returning to FIG. 2, in operation 90, the doped silicon oxide film is then annealed at a temperature above the film glass transition temperature, as described above. In some embodiments, reflow of the film may occur.

Referring to FIG. 8, in some embodiments, vertical slits 130 may be etched into the substrate after depositing and annealing the doped oxide film. FIG. 8 shows a side view of the substrate 100 after vertical slits 130 are etched.

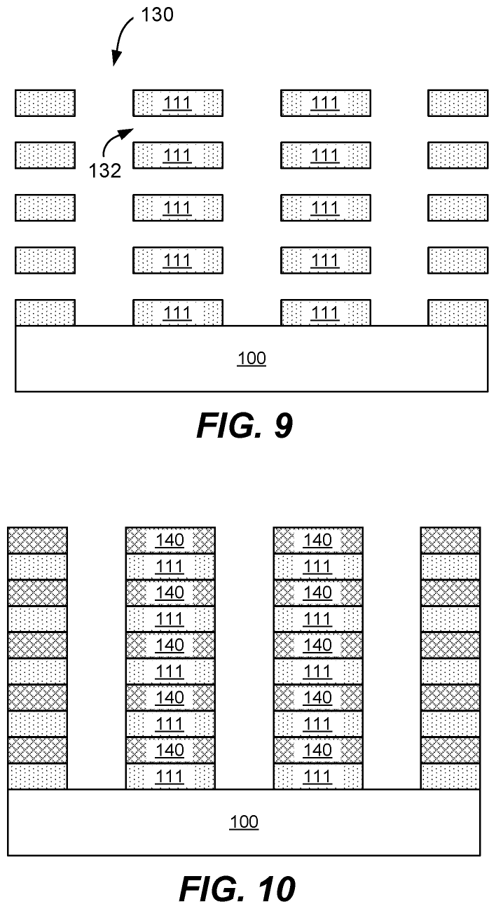

In some embodiments, nitride layer in the ONON stack is etched relative to oxide on the substrate. Etching may be performed using a selective etch process, in which nitride layer is etched at a faster rate than etching of oxide. A suitable selective etch process may be dry or wet. For example, a suitable dry selective nitride layer etch may be conducted by exposing the substrate to any one or more of the following gases: chlorine (Cl₂), oxygen (O₂), nitrous oxide (N₂O), tetrafluoromethane (CF₄), sulfur tetrafluoride (SF₄), carbon dioxide (CO₂), fluoromethane (CH₃F), nitrogen trifluoride (NF₃), nitrogen (N₂), hydrogen (H₂), ammonia (NH₃), methane (CH₄), sulfur hexafluoride (SF₆), argon (Ar), carbonyl sulfide (COS), carbon disulfide (CS₂), hydrogen sulfide (H₂S), and nitric oxide (NO). In this operation, etch species may flow into the vertical slits 130 and selectively laterally etch nitride, removing the nitride layers from the ONON stack. Alternatively, the nitride layer in the ONON stack may be etched using a wet etch process, such as by exposing the substrate to phosphoric acid (H₃PO₄) and/or diluted hydrofluoric acid (“DHF”) or a mixture of these solutions. FIG. 9 shows an example schematic illustration of a substrate 100 with horizontal gaps 132 formed from etching nitride.

In some embodiments a conductor, typically tungsten, is deposited into the gaps of the substrate to form wordlines. Tungsten may be deposited by any suitable technique, such as ALD, CVD, PEALD, and/or PECVD. In some embodiments, a barrier layer and/or a tungsten nucleation layer is deposited prior to depositing bulk tungsten. FIG. 10 shows an example of a substrate 100 including deposited tungsten wordlines 140 where nitride 112 was previously.

It should also be understood that in other embodiments an alternative to the ONON stack may be a stack of deposited alternating dielectric and conductive layers. One example of this is a stack composed of alternating oxide polysilicon layers, sometimes referred to as an OPOP stack. Such an OPOP stack can be etched to form a staircase pattern according to known techniques, avoiding the need for nitride replacement with tungsten in the ONON stack, as described above.

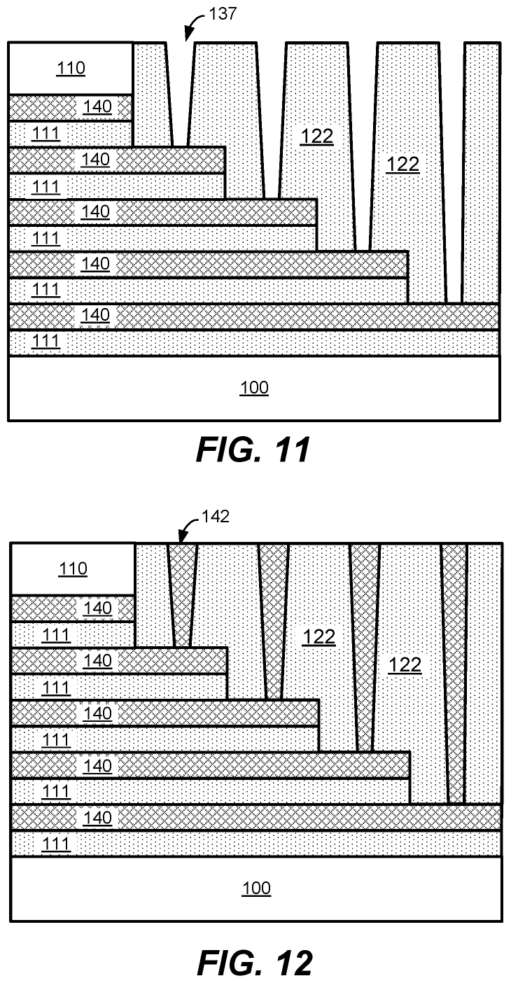

Referring to FIG. 11, in some embodiments, the doped oxide film 122 is vertically etched to form vias 137. The doped oxide film 122 may be etched by dry etching using exposure to one or more of the following gases: O₂, Ar, C₄F₆, C₄F₈, SF₆, CHF₃, and CF₄. FIG. 11 shows an example substrate 100 including the oxide/conductor stack in a staircase pattern whereby vias 137 are etched in the doped oxide 122.

Referring to FIG. 12, in some embodiments, a conductor, e.g., tungsten, may be deposited in the vias 137 to form interconnects 142 to the wordlines to complete the 3D NAND structure.

Accordingly, another aspect involves a method of conducting a large area gap fill in fabrication of a 3D NAND structure. The method involves providing a patterned semiconductor substrate comprising a 3D NAND structure having alternating oxide and nitride or polysilicon layers in a staircase pattern, depositing on the patterned semiconductor substrate over the staircase pattern a doped silicon oxide film configured to expand upon annealing at a temperature above the film's glass transition temperature, and annealing the doped silicon oxide film to a temperature above the film glass transition temperature. In some embodiments, reflow of the film may occur. The doped silicon oxide film is deposited by a chemical vapor deposition (CVD) process using precursors for silicon oxide, a B dopant and, optionally, a P dopant. The silicon oxide precursor may be tetraethyl orthosilicate (TEOS), and suitable dopant precursors are triethylborate (TEB) and triethylphosphate (TEPO) for the B and P dopants, respectively, although others may be used. Other potential features, including material composition, dimensions and properties, are described herein above.

And accordingly, another aspect involves a semiconductor device, including a 3D NAND structure having alternating oxide and nitride or polysilicon layers in a staircase pattern, and a doped silicon oxide film disposed and annealed on the staircase pattern. The doped silicon oxide film disposed and annealed on the staircase pattern expands upon annealing and exhibits substantially zero as-deposited stress and substantially zero stress shift post-anneal. Other potential features of such a device, including material composition, dimensions and properties, are described herein above, with reference to the fabrication methods.

### Apparatus

Another aspect involves an apparatus for processing a semiconductor substrate by depositing on a patterned semiconductor substrate a doped silicon oxide film, the apparatus including: a reaction chamber including the substrate; a plasma source coupled to the reaction chamber and configured to generate a plasma outside the reaction chamber; one or more first gas inlets coupled to the reaction chamber; a second gas inlet coupled to the reaction chamber; and a controller including instructions for performing the following operations: depositing on a patterned semiconductor substrate disposed in the chamber a doped silicon oxide film configured to expand upon annealing at a temperature above the film's glass transition temperature; and annealing the doped silicon oxide film to a temperature above the film glass transition temperature. The instructions may further include that the doped silicon oxide film be deposited by a chemical vapor deposition (CVD) based process using reactants for silicon oxide and a carbon dopant. The CVD process may be a plasma enhanced CVD (PECVD) process. The composition and processing conditions of the doped silicon oxide film may be tailored so that the film exhibits substantially zero as-deposited stress and substantially zero stress shift post-anneal. The description that following provides some details of apparatus, semiconductor chambers and tools suitable for implementation of the methods described herein and to fabricate the described devices.

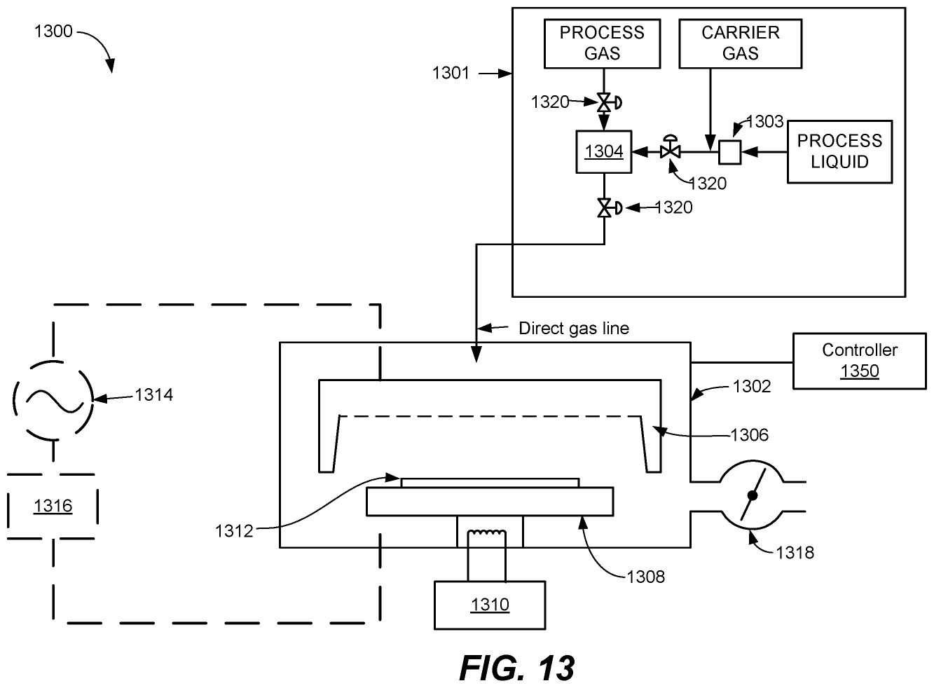

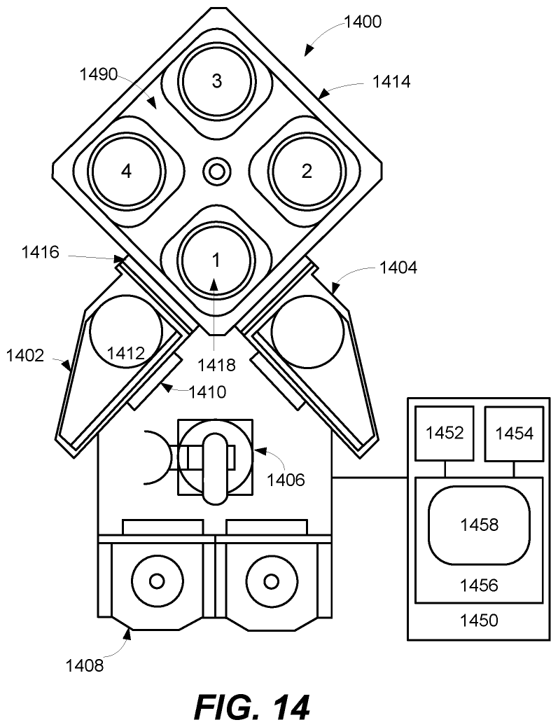

FIG. 13 depicts a schematic illustration of an embodiment of deposition process chamber 1300 that may be suitable for depositing and processing films as described herein. The chamber may be operated as a chemical vapor deposition (CVD) chamber, in particular a plasma enhanced CVD (PECVD) chamber. The chamber 1300 has a process chamber body 1302 for maintaining a low pressure environment. A plurality of process stations 1300 may be included in a common low pressure process tool environment. For example, FIG. 14 depicts an embodiment of a multi-station processing tool 1400.

Referring again to FIG. 13, process station 1300 fluidly communicates with reactant delivery system 1301 for delivering process gases to a distribution showerhead 1306. Reactant delivery system 1301 includes a mixing vessel 1304 for blending and/or conditioning process gases, such as a silicon oxide precursor gas (e.g., TEOS) or second reactant gas (e.g., a dopant reactant), for delivery to showerhead 1306. One or more mixing vessel inlet valves 1320 may control introduction of process gases to mixing vessel 1304. Plasma may also be delivered to the showerhead 1306 or may be generated in the process station 1300. Reactant delivery system 1301 may be configured to deliver process gases for depositing a doped oxide film over a substrate provided in the process station 1300.

As an example, the embodiment of FIG. 13 includes a vaporization point 1303 for vaporizing liquid reactant to be supplied to the mixing vessel 1304. In some embodiments, vaporization point 1303 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 1303 may be heat traced. In some examples, mixing vessel 1304 may also be heat traced. In one non limiting example, piping downstream of vaporization point 1303 has an increasing temperature profile extending from approximately 100° C. to approximately 150° C. at mixing vessel 1304.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 1303. In one scenario, a liquid injector may be mounted directly to mixing vessel 1304. In another scenario, a liquid injector may be mounted directly to showerhead 1306.

In some embodiments, a liquid flow controller (LFC) upstream of vaporization point 1303 may be provided for controlling a mass flow of liquid for vaporization and delivery to process station 1300. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 1306 distributes process gases toward substrate 1312. In the embodiment shown in FIG. 13, the substrate 1312 is located beneath showerhead 1306 and is shown resting on a pedestal 1308. Showerhead 1306 may have any suitable shape and may have any suitable number and arrangement of ports for distributing process gases to substrate 1312.

In some embodiments, pedestal 1308 may be raised or lowered to expose substrate 1312 to a volume between the substrate 1312 and the showerhead 1306. It will be appreciated that, in some embodiments, pedestal height may be adjusted programmatically by a suitable computer controller 1350.

In another scenario, adjusting a height of pedestal 1308 may allow a plasma density to be varied during plasma activation cycles in the process in embodiments where a plasma is ignited. At the conclusion of the process phase, pedestal 1308 may be lowered during another substrate transfer phase to allow removal of substrate 1312 from pedestal 1308.

In some embodiments, pedestal 1308 may be temperature controlled via heater 1310. In some embodiments, the pedestal 1308 may be heated to a temperature of at least about 400° C., or in some embodiments, less than about 300° C., such as about 250° C., during deposition of silicon nitride films as described in disclosed embodiments. In some embodiments, the pedestal is set at a temperature between about 400° C. and about 600° C. for doped oxide film deposition. In some embodiments, the pedestal is set at a temperature between about 500° C. and about 950° C. for annealing of a doped oxide film, as described herein.

Further, in some embodiments, pressure control for process station 1300 may be provided by butterfly valve 1318. As shown in the embodiment of FIG. 13, butterfly valve 1318 throttles a vacuum provided by a downstream vacuum pump (not shown). However, in some embodiments, pressure control of process station 1300 may also be adjusted by varying a flow rate of one or more gases introduced to the process station 1300.

In some embodiments, a position of showerhead 1306 may be adjusted relative to pedestal 1308 to vary a volume between the substrate 1312 and the showerhead 1306. Further, it will be appreciated that a vertical position of pedestal 1308 and/or showerhead 1306 may be varied by any suitable mechanism within the scope of the present disclosure. In some embodiments, pedestal 1308 may include a rotational axis for rotating an orientation of substrate 1312. It will be appreciated that, in some embodiments, one or more of these example adjustments may be performed programmatically by one or more suitable computer controllers 1350.

In some embodiments where plasma may be used as discussed above, showerhead 1306 and pedestal 1308 electrically communicate with a radio frequency (RF) power supply 1314 and matching network 1316 for powering a plasma. In some embodiments, the plasma energy may be controlled by controlling one or more of a process station pressure, a gas concentration, an RF source power, an RF source frequency, and a plasma power pulse timing. For example, RF power supply 1314 and matching network 1316 may be operated at any suitable power to form a plasma having a desired composition of radical species. Examples of suitable powers are included above. Likewise, RF power supply 1314 may provide RF power of any suitable frequency. In some embodiments, RF power supply 1314 may be configured to control high- and low-frequency RF power sources independently of one another. Example low frequency RF frequencies may include, but are not limited to, frequencies between 0 kHz and 500 kHz. Example high-frequency RF frequencies may include, but are not limited to, frequencies between 1.8 MHz and 2.45 GHz, or greater than about 13.56 MHz, or greater than 27 MHz, or greater than 180 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, one or more hardware parameters of the process station 1300, including those discussed in detail below, may be adjusted programmatically by one or more computer controllers 1350.

In some embodiments, instructions for a controller 1350 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. It will be appreciated that these recipe phases may be further subdivided and/or iterated in any suitable way within the scope of the disclosed embodiments.

As described above, one or more process chambers may be included as stations in a multi station processing tool. FIG. 14 shows a schematic view of an embodiment of a multi station processing tool 1400 that includes a processing chamber 1414 having a plurality of processing stations in a low-pressure environment. The processing chamber 1414 may be configured to maintain a low pressure environment so that substrates may be transferred among the process stations without experiencing a vacuum break and/or air exposure.

The tool 1400 further includes an inbound load lock 1402 and an outbound load lock 1404, either or both of which may include a remote plasma source. A robot 1406 at atmospheric pressure is configured to move wafers from a cassette loaded through a pod 1408 into inbound load lock 1402 via an atmospheric port 1410. A wafer is placed by the robot 1406 on a pedestal 1412 in the inbound load lock 1402, the atmospheric port 1410 is closed, and the load lock is pumped down. Where the inbound load lock 1402 includes a remote plasma source, the wafer may be exposed to a remote plasma treatment in the load lock prior to being introduced into a processing chamber 1414. Further, the wafer also may be heated in the inbound load lock 1402 as well, for example, to remove moisture and adsorbed gases. Next, a chamber transport port 1416 to processing chamber 1414 is opened, and another robot (not shown) places the wafer into the reactor on a pedestal of a first station shown in the reactor for processing. While the embodiment depicted in FIG. 14 includes load locks, it will be appreciated that, in some embodiments, direct entry of a wafer into a process station may be provided.

The depicted processing chamber 1414 includes four process stations, numbered from 1 to 4 in the embodiment shown in FIG. 14. Each processing station may be configured to deposit TEOS-based silicon dioxide and silane-based silicon nitride. Each processing station is supplied by a common mixing vessel (1304, for example in FIG. 13) for blending and/or conditioning process gases prior to delivery to each processing station. Each process station depicted in FIG. 14 includes a process station substrate holder (shown at 1418 for station 1) and process gas delivery line inlets. In some embodiments, one or more process station substrate holders 1418 may be heated.

In some embodiments, each process station may have different or multiple purposes. For example, a process station may be switchable between an ultra-smooth PECVD process mode and a conventional PECVD or CVD mode. Additionally, or alternatively, in some embodiments, processing chamber 1414 may include one or more matched pairs of ultra-smooth PECVD and conventional PECVD stations (e.g., a pair including an ultrasmooth PECVD SiO₂ station and a conventional PECVD SiN station). In another example, a process station may be switchable between two or more film types, so that stacks of different film types may be deposited in the same process chamber. While the depicted processing chamber 1414 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 14 also depicts an embodiment of a substrate handling system 1490 for transferring substrates within processing chamber 1414. In some embodiments, substrate handling system 1490 may be configured to transfer substrates between various process stations and/or between a process station and a load lock. It will be appreciated that any suitable substrate handling system may be employed. Non-limiting examples include substrate carousels and substrate handling robots.

The multi-station processing tool 1400 also includes an embodiment of a system controller 1450 employed to control process conditions and hardware states of processing tool 1400. For example, in some embodiments, system controller 1450 may control one or more process parameters during a PECVD film deposition phase to control features of a deposited film, including the composition and thickness of the deposited film, etc.

System controller 1450 may include one or more memory devices 1456, one or more mass storage devices 1454, and one or more processors 1452. Processor 1452 may include a CPU or computer, analog and/or digital input/output connections, stepper motor controller boards, etc.

In some embodiments, system controller 1450 controls all of the activities of processing tool 1400. System controller 1450 executes machine-readable system control software 1458 stored in mass storage device 1454, loaded into memory device 1456, and executed on processor 1452. System control software 1458 may include instructions for controlling the timing, mixture of gases, chamber and/or station pressure, chamber and/or station temperature, substrate temperature, target power levels, RF power levels, substrate pedestal, chuck and/or susceptor position, and other parameters of a particular process performed by processing tool 1400. System control software 1458 may be configured in any suitable way. For example, various process tool component subroutines or control objects may be written to control operation of the process tool components for performing various process tool processes. System control software 1458 may be coded in any suitable computer readable programming language.

In some embodiments, system control software 1458 may include input/output control (IOC) sequencing instructions for controlling the various parameters described above. For example, each phase of a PECVD process may include one or more instructions for execution by system controller 1450. The instructions for setting process conditions for a PECVD process phase may be included in a corresponding PECVD recipe phase, for example a thick doped silicon oxide film deposition as described herein. In some embodiments, the PECVD recipe phases may be sequentially arranged, so that all instructions for a PECVD process phase are executed concurrently with that process phase.

Other computer software and/or programs stored on mass storage device 1454 and/or memory device 1456 associated with system controller 1450 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto process station substrate holder 1418 and to control the spacing between the substrate and other parts of processing tool 1400.

A process gas control program may include code for controlling gas composition and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations.

In some embodiments, there may be a user interface associated with system controller 1550. The user interface may include a display screen, graphical software displays of the apparatus and/or process conditions, and user input devices such as pointing devices, keyboards, touch screens, microphones, etc.

In some embodiments, parameters adjusted by system controller 1450 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 1450 from various process tool sensors. The signals for controlling the process may be output on the analog and digital output connections of processing tool 1400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 1450 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

In some implementations, the system controller 1450 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 1450, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 1450 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 1450 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 1450, in some implementations, may be a part of or coupled to a computer that is integrated with, coupled to the system, otherwise networked to the system, or a combination thereof. For example, the system controller 1450 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 1450 receives instructions in the form of data, which specify parameters for each of the processing steps to be performed during one or more operations. It should be understood that the parameters may be specific to the type of process to be performed and the type of tool that the system controller 1450 is configured to interface with or control. Thus as described above, the system controller 1450 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a chemical vapor deposition (CVD/PECVD) chamber or module, a plasma etch chamber or module, a track chamber or module, and any other semiconductor processing systems that may be associated or used in the fabrication and/or manufacturing of semiconductor wafers. Etching operations described herein, such as for etching nitride or oxide, may be performed in any suitable process chamber. In some embodiments, substrates may be etched in an adjustable gap capacitively coupled confined RF plasma reactor that may be used for performing the etching operations described herein.

As noted above, depending on the process step or steps to be performed by the tool, the system controller 1450 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

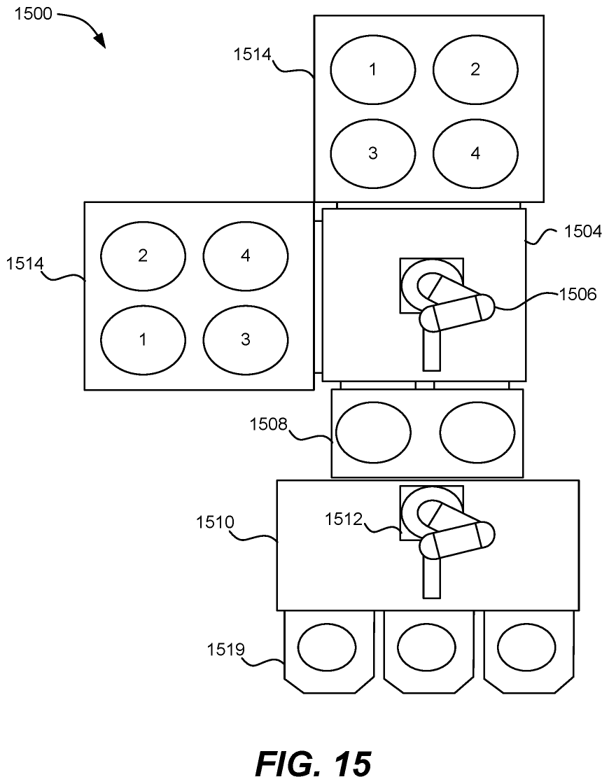

It will be appreciated that, in some embodiments, a low-pressure transfer chamber may be included in a multi-station processing tool to facilitate transfer between a plurality of processing chambers. For example, FIG. 15 schematically shows another embodiment of a multi-station processing tool 1500. In the embodiment shown in FIG. 15, multi-station processing tool 1500 includes a plurality of processing chambers 1514 including a plurality of process stations (numbered 1 through 4). Processing chambers 1514 are interfaced with a low-pressure transport chamber 1504 including a robot 1506 configured to transport substrates between processing chambers 1514 and load lock 1519. An atmospheric substrate transfer module 1510, including an atmospheric robot 1512, is configured to facilitate transfer of substrates between load lock 1519 and pod 1508. While not shown in FIG. 15, it will be appreciated that the embodiment of multi-station processing tool 1500 may include a suitable system controller like the embodiment of system controller 1450 shown in and described with reference to FIG. 14.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for plasma enhanced chemical vapor deposition of carbon-doped silicon oxide film on a substrate comprising:
providing the substrate in a deposition chamber at a substrate temperature of less than about 700° C.;
generating a plasma of a process gas comprising a silicon-containing gas source and a carrier gas, and a carbon-containing gas source;
contacting the substrate with the plasma in the deposition chamber; and
depositing a thin film of carbon-doped silicon dioxide on the substrate, the thin film having a Young's modulus of at least 70 GPa.

2. The method of claim 1, wherein the silicon-containing gas source is a gas of a compound of the formula 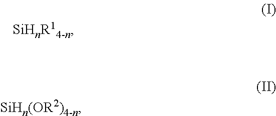
O(Si(R³₃))₂ (III) or a combination thereof,
wherein R¹, R² and R³ are each independently optionally substituted aliphatic, optionally substituted alkyl, optionally substituted heteroalkyl, optionally substituted aryl, optionally substituted heteroaryl, optionally substituted cyclyl or optionally substituted heterocyclyl, and
n is an integer of 0 to 4.

3. The method of claim 1, wherein the silicon-containing gas source comprises silane, tetramethylsilane, tetramethoxysilane, tetraethoxysilane, hexamethyldisilazane, hexamethyl disiloxane or a combination thereof.

4. The method of claim 3, wherein the silicon-containing gas source comprises tetramethylsilane and silane.

5. The method of claim 1, wherein the carbon-containing gas source comprises carbon dioxide, carbon monoxide, methane, ethane or a combination thereof.

6. The method of claim 5, wherein the carbon-containing gas source further comprises a carrier gas of argon, helium, hydrogen, nitrous oxide, nitrogen or a combination thereof.

7. The method of claim 1, wherein the carbon-doped silicon oxide film has a modulus of at least 90 GPa.

8. The method of claim 1, wherein the carbon-doped silicon oxide film has about 5% (atomic) carbon content or less.

9. The method of claim 1, wherein a pressure in the deposition chamber is maintained between about 1 and about 8 Torr.

10. The method of claim 1, wherein the substrate temperature is greater than about 400° C. and less than about 650° C.

11. The method of claim 1, wherein a ratio of the carbon-containing gas source to the silicon-containing gas source is between about 150:1 to about 10:1.

12. The method of claim 1, wherein the plasma is generated in situ or remotely.

13. The method of claim 12, wherein the thin film has a thickness of less than 300 angstroms.

14. The method of claim 12, wherein the thin film has a dielectric constant of about 4 to about 4.5.

15. An apparatus for forming a carbon-doped silicon oxide film on a substrate, the apparatus comprising:
a reaction chamber;
a substrate support configured to support the substrate in the reaction chamber;
one or more inlet for introducing reactants to the reaction chamber;
one or more outlet for removing material from the reaction chamber;
a plasma generator configured to deliver a plasma to the reaction chamber; and
a controller having at least one processor and a memory, wherein the at least one processor and the memory are communicatively connected with one another, and the memory stores computer-executable instructions for controlling the at least one processor to cause:
(i) receiving the substrate in the reaction chamber,
(ii) flowing a process gas comprising a silicon-containing source into the reaction chamber, and
(iii) generating and delivering the plasma from a carbon-containing gas source to the reaction chamber to form the carbon-doped silicon oxide film on the substrate, wherein the carbon-doped silicon oxide film comprises:
(1) a Young's modulus of about 90 GPa or greater, and
(2) a dielectric constant of about 4 to about 4.5.

16. The apparatus of claim 15, wherein the carbon-doped silicon oxide film has a thickness of less than 300 angstroms.

17. The apparatus of claim 15, wherein the carbon-doped silicon oxide film has a carbon content of about 5% (atomic) or less.
